(19) United States
(12) Patent Application Publication
(10) Pub. No.: US 2014/0034919 A1
(43) Pub. Date: Feb. 6, 2014

(54) ORGANIC LIGHT EMITTING DISPLAY DEVICE WITH ENHANCED LIGHT EFFICIENCY AND MANUFACTURING METHOD THEREOF

(71) Applicant: SAMSUNG DISPLAY CO., LTD., Yongin-city (KR)

(72) Inventors: Chan-Young Park, Yongin-si (KR); Young-Suk Cho, Seoul (KR); Sung-Jin Choi, Hwaseong-si (KR)

(73) Assignee: Samsung Display Co., Ltd., Yongin-city (KR)

(21) Appl. No.: 13/842,333

(22) Filed: Mar. 15, 2013

(30) Foreign Application Priority Data
Aug. 2, 2012 (KR) 10-2012-0084771

(51) Int. Cl. H01L 51/52; H01L 51/56

(52) U.S. Cl. CPC H01L 51/5275; H01L 51/56
USPC 257/40; 438/27

(57) ABSTRACT

An organic light emitting display device and a manufacturing method thereof are disclosed. In one aspect, the device includes a substrate, a first electrode formed over the substrate, an emission layer formed on the first electrode and a second electrode formed on the emission layer. The device also includes an encapsulation layer formed on the second electrode and a lens layer comprising a plurality of lenses formed in the encapsulation layer.

### CROSS-REFERENCE TO RELATED APPLICATIONS

This application is based on and claims priority from Korean Patent Application No. 10-2012-0084771 filed on Aug. 2, 2012, with the Korean Intellectual Property Office, the present disclosure of which is incorporated herein in its entirety by reference.

### TECHNICAL FIELD

The present disclosure generally relates to an organic light emitting display device and a manufacturing method thereof, and more particularly, to an organic light emitting display device with enhanced light efficiency and a manufacturing method thereof.

### BACKGROUND

An organic light emitting display is self-emissive and includes an organic light emitting diode (OLED) which emits light to display an image. Since the OLED display does not require a separate light source, unlike a liquid crystal display, it is possible to relatively reduce its thickness and weight. Further, since the OLED device has characteristics such as low power consumption, high luminance, and high response speed, the technology has been rapidly adopted for use as a display in a portable computing device such as a smartphone or tablet computer.

### SUMMARY

One inventive aspect is an organic light emitting display device capable of enhancing light emission efficiency.

Another aspect is an organic light emitting display device capable of enhancing light emission efficiency by forming a lens layer on an encapsulation layer formed for protecting an internal structure such as an emission layer and an electrode.

Another aspect is an organic light emitting display device, including: a substrate; a first electrode formed on the substrate; an emission layer formed on the first electrode; a second electrode formed on the emission layer; and an encapsulation layer formed on the second electrode, in which a lens layer having a plurality of lenses is provided in the encapsulation layer.

The encapsulation layer may include an inorganic layer and an organic layer which are alternately laminated.

The inorganic layers and the organic layers may be laminated with 2 to 30 layers, respectively.

The lens layer may be made of an organic material.

The organic material for forming the lens layer may include an acryl-based polymer resin. The acryl-based polymer resin may include polymethylmethacrylate (PMMA).

A planarization layer made of an organic material may be disposed on the lens layer.

A pixel defining layer may be disposed at an edge of the first electrode to section the first electrode by a pixel unit and define pixel areas, and the respective lenses formed on the lens layer may be disposed at positions corresponding to the respective pixel areas. The lens may occupy ½ or more of an area of the pixel area.

Another aspect is a method of manufacturing an organic light emitting display device, including: forming a first electrode on a substrate; forming an emission layer on the first electrode; forming a second electrode on the emission layer; and forming an encapsulation layer on the second electrode, in which the forming of the encapsulation layer includes forming a lens layer having a plurality of lenses.

In the forming of the encapsulation layer, forming an inorganic layer made of an inorganic material and forming an organic layer made of an organic material may be alternately performed.

The forming of the inorganic layer and the forming of the organic layer may be alternately performed 2 to 30 times, respectively.

The forming of the encapsulation layer may include forming a lower encapsulation layer, forming a lens layer, and forming an upper encapsulation layer.

The forming of the lens layer may include forming an organic layer on the lower encapsulation layer; forming a plurality of lens shapes by disposing a mold with a lens shape on the organic layer and pressing the organic layer; and curing the plurality of lens shapes.

The curing may include irradiating light to the plurality of lens shapes.

The organic material may be an acryl-based polymer.

The acryl-based polymer may include polymethylmethacrylate (PMMA).

The method of manufacturing an organic light emitting display device may further include forming a pixel defining layer at the edge of the first electrode, after the forming of the first electrode, in which in the forming of the lens layer, the respective lenses may be formed at positions corresponding to the pixel areas defined by the pixel defining layer.

In the forming of the lens layer, the lens may occupy ½ or more of an area of the pixel area.

### BRIEF DESCRIPTION OF THE DRAWINGS

FIG. 1 is a cross-sectional view schematically illustrating a structure of an organic light emitting display device according to an embodiment.

FIG. 2 is a schematic cross-sectional view illustrating an organic light emitting display device according to one embodiment, in which particularly, a substrate and a lower structure are illustrated in more detail.

FIG. 3 is a cross-sectional view illustrating an encapsulation layer and a lens layer included in the encapsulation layer in the organic light emitting display device according to one embodiment in more detail.

FIG. 4 is a diagram for describing a phenomenon in which an image is blurred by a lens.

FIG. 5 is a partial perspective view illustrating a lens layer in the organic light emitting display device according to one embodiment, in which shapes of a plurality of lenses formed on the lens layer are illustrated.

FIG. 6 is a diagram illustrating an example of a mold for forming a lens layer.

FIGS. 7A to 7H are diagrams schematically illustrating a manufacturing process of an organic light emitting display device according to another embodiment.

### DETAILED DESCRIPTION

In general, an OLED display includes a hole injection electrode, an organic emission layer, and an electron injection electrode. A hole supplied from the hole injection electrode and an electron supplied from the electron injection electrode are coupled with each other in the organic emission layer to form an exciton, and light is generated when the exciton falls in a ground state.

Generally, however, the light efficiency of an OLED display is not high (about 20%). Accordingly, to enhance light emission efficiency, the amount of light emitted needs to be increased.

Hereinafter, the present disclosure will be described in more detail with reference to embodiments illustrated in the drawings. However, the scope of the present disclosure is not limited to the following embodiments and drawings. The drawings only select and illustrate an example suitable for describing the present disclosure among various embodiments.

Respective elements and shapes thereof were schematically drawn or exaggeratedly drawn in the accompanying drawings for easy understanding, and elements in a real product are not illustrated and omitted. Therefore, the drawings should be analyzed in order to help understanding the present invention. Meanwhile, like reference numerals designate like elements playing the same role in the drawings.

Further, it will be understood that when a layer or an element is described as being “on” another layer or element, it may be directly disposed on another layer or element, or an intervening layer may also be present therebetween.

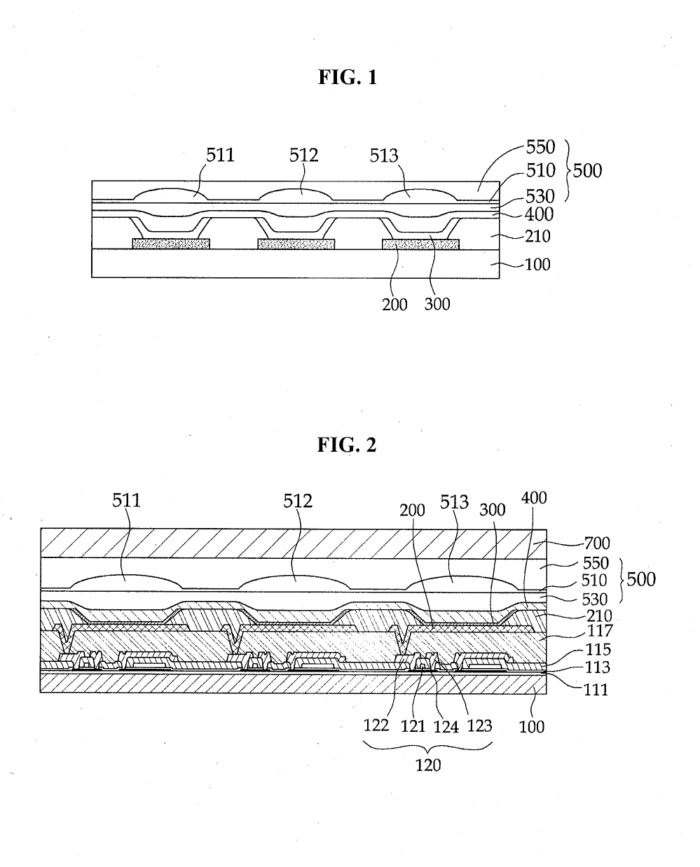

An organic light emitting display device according to an embodiment includes a substrate 100, a first electrode 200 formed on the substrate, an emission layer 300 formed on the first electrode, a second electrode 400 formed on the emission layer, and an encapsulation layer 500 formed on the second electrode, as illustrated in FIG. 1. Here, a lens layer 510 including a plurality of lenses 511, 512, and 513 is provided in the encapsulation layer 500.

FIG. 1 illustrates a top emission type organic light emitting display device in which light generated from the emission layer is displayed through the second electrode 400 direction which is opposite to the substrate 100. Hereinafter, embodiments are described based on the top emission type organic light emitting display device as illustrated in FIG. 1.

Meanwhile, FIG. 2 is a schematic cross-sectional view illustrating the organic light emitting display device according to one embodiment, in which particularly, the substrate 100 and a lower structure are illustrated in more detail.

First, the substrate 100 may be made of glass or polymer plastic which is generally used in the organic light emitting display device. The substrate 100 may be transparent or may not be transparent. The substrate 100 may be properly selected and used according to the need of those skilled in the art. The first electrode 200 is disposed on the substrate 100.

Although not illustrated in FIG. 1, a plurality of thin film transistors 120 may be formed on the substrate 100 before forming the first electrode 200 (see FIG. 2).

In another embodiment illustrated in FIG. 2, the thin film transistor 120 includes a gate electrode 121, a drain electrode 122, a source electrode 123, and a semiconductor layer 124 which are formed on the substrate 100. Further, a gate insulating layer 113 and an interlayer insulating layer 115 are provided in the thin film transistor 120. The structure of the thin film transistor 120 is not limited to the form illustrated in FIG. 2 and may be configured in another form. Further, as the thin film transistor 120, various thin film transistors such as an organic thin film transistor in which the semiconductor layer 124 is made of an organic material and a silicon thin film transistor in which the semiconductor layer 124 is made of silicon may be used. A buffer layer 111 made of silicon oxide, silicon nitride, or the like may be further provided between the thin film transistor 120 and the first substrate 100 if necessary.

The first electrode 200, the organic layer 300 and the second electrode 400 are sequentially formed above the thin film transistors 120. The first electrode 200, the organic layer 300 and the second electrode 400 may be referred to as an “organic light emitting diode unit” together.

In FIGS. 1 and 2, the first electrode 200 is an anode as a pixel electrode electrically connected to the thin film transistor 120, and the second electrode 400 is a cathode.

The first electrode 200 is electrically connected with the thin film transistor 120 therebelow. In this case, when a planarization layer 117 covering the thin film transistor 120 is provided, the first electrode 200 is disposed on the planarization layer 117, and the first electrode 200 is electrically connected to the thin film transistor 120 through a contact hole provided in the planarization layer 117.

The first electrode 200 may be provided as a transparent electrode or a reflective electrode. When configured as the transparent electrode, the first electrode 200 may be made of ITO, IZO, ZnO or In₂O₃, and when configured as the reflective electrode, the first electrode 200 may include a reflective layer made of Ag, Mg, Al, Pt, Pd, Au, Ni, Nd, Ir, Cr or a compound thereof and a layer made of ITO, IZO, ZnO or In₂O₃ thereon. In the case where the first electrode 200 is the anode, as a material of the first electrode 200, for example, ITO may be used.

In FIGS. 1 and 2, the first electrode 200 serves as the anode and the second electrode 400 serves as the cathode, but polarities of the first electrode 200 and the second electrode 400 may also be reversed.

A pixel defining layer 210 is provided between the first and second electrodes 200 and 400. The pixel defining layer 210 is made of an insulative material and sections the first electrode 200 by a pixel unit. In detail, the pixel defining layer 210 is disposed at an edge of the first electrode 200 to section the first electrode by a pixel unit and define pixel areas. That is, the pixel defining layer (PDL) 210 covers the edge of the first electrode 200. The pixel defining layer 210 serves to define the pixel area and serves to prevent a short circuit between the first electrode 200 and the second electrode 400 by increasing a gap between the edge of the first electrode 200 and the second electrode 400 to prevent an electric field from being concentrated at the edge of the first electrode 200.

The emission layer 300 is provided between the first electrode 200 and the second electrode 400. That is, the emission layer 300 is formed in an opening of the first electrode 200 sectioned by the pixel defining layer 210. At least one of a hole injection layer, a hole transport layer, an electron transport layer and an electron injection layer in addition to the emission layer 300 may be provided between the first electrode 200 and the second electrode 400. The emission layer 300, the hole injection layer, the hole transport layer, the electron transport layer and the electron injection layer are referred to as an organic layer together. The organic layer may be made of a low-molecular organic material or a high-molecular organic material.

The low-molecular organic material may be applied to all of the hole injection layer, the hole transport layer, the emission layer, the electron transport layer and the electron injection layer. The low-molecular organic material may be laminated in a single or complex structure, and the applicable organic material includes copper phthalocyanine (CuPc), N,N′-Di(naphthalene-1-yl)-N,N′-diphenyl-benzidine (NPB), tris-8-hydroxyquinoline aluminum (Alq₃), and the like. The low-molecular organic material may be formed into a thin film by a method such as vacuum deposition using a mask.

The high-molecular organic material may be applied to, for example, a hole transport layer (HTL) and an emission layer (EML). In this case, the hole transport layer may be made of, for example, PEDOT, and the emission layer may be made of, for example, poly-phenylenevinylenes-based and polyfluorenes-based high-molecular organic materials.

The second electrode 400 is formed on the emission layer 300 and the pixel defining layer 210. The second electrode 400 may be made of a material which is generally used in the art. The second electrode 400 may also be provided as a transparent electrode or a reflective electrode. When provided as the transparent electrode, the second electrode 400 may include a layer made of Li, Ca, LiF/Ca, LiF/Al, Al, Mg or a compound thereof and a layer made of a material for forming a transparent electrode such as ITO, IZO, ZnO or In₂O₃ thereon. When provided as the reflective electrode, the second electrode 400 may be provided by depositing Li, Ca, LiF/Ca, LiF/Al, Al, Mg or a compound thereof. In the exemplary embodiment illustrated in FIGS. 1 and 2, since the top emission type organic light emitting display device is described, the second electrode 400 may be manufactured as the transparent electrode. For example, the second electrode 400 may be formed by using LiF/Al.

The encapsulation layer 500 is formed on the second electrode. A window member 700 made of a material such as glass or plastic may be disposed on the encapsulation layer 500 (see FIG. 2). The window member 700 may be disposed to contact to the encapsulation layer 500 and to be separated from the encapsulation layer 500.

Although not illustrated in the drawing, the window member 700 may be sealed together with the substrate 100 by a sealing member in an opposed state to the substrate 100. As a result, the organic light emitting display device illustrated in FIG. 2 may be obtained.

Hereinafter, the encapsulation layer 500 will be described in detail. The encapsulation layer 500 is also referred to as a capping layer or a sealing layer. The encapsulation layer 500 serves to protect the organic light emitting diode elements 200, 300, and 400 from an external environment.

The encapsulation layer 500 may be formed in a single layer and may be formed in a multilayer, and in one embodiment, the encapsulation layer 500 is formed in the multilayer which includes a plurality of thin film layers.

The lens layer 510 is provided in the encapsulation layer 500. Meanwhile, the encapsulation layer 500 may be divided into a lower encapsulation layer 530 and an upper encapsulation layer 550 based on the lens layer 510. All of the lens layer 510, the lower encapsulation layer 530 and the upper encapsulation layer 550 form the encapsulation layer 500.

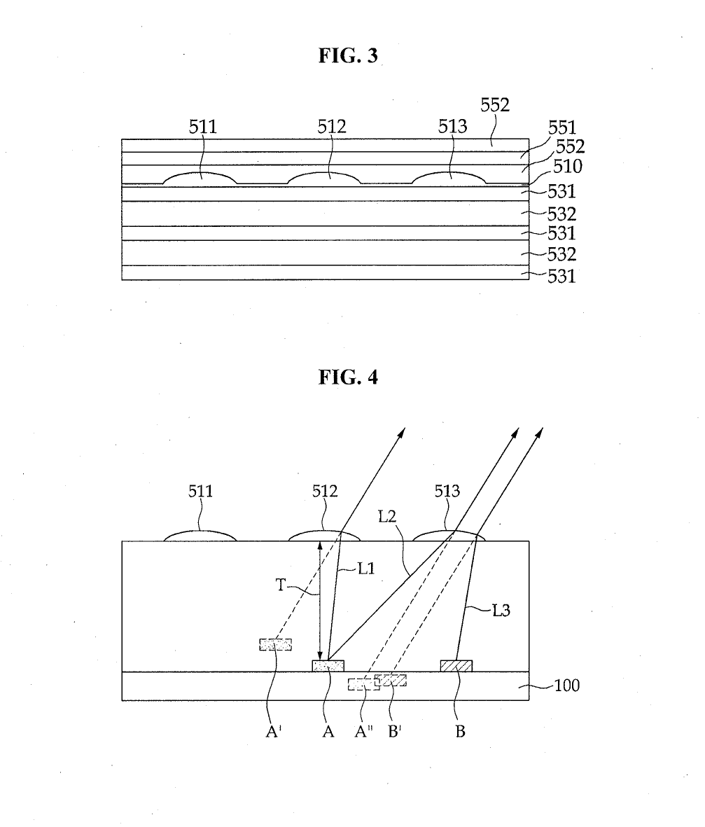

FIG. 3 illustrates a structure of an encapsulation layer and a lens layer included in the encapsulation layer in the organic light emitting display device according to one embodiment. As illustrated in FIG. 3, the encapsulation layer includes inorganic layers 531 and 551 and organic layers 532 and 552 which are alternately laminated. Meanwhile, the inorganic layers and the organic layers may be divided into lower encapsulation layers 531 and 532 and upper encapsulation layers 551 and 552 based on the lens layer 510.

The encapsulation layer 500 may be thickly formed in several layers from the viewpoint of protecting the organic light emitting diode unit such as the emission layer 300 and the electrodes 200 and 400. However, the encapsulation layer 500 may be thinly formed from the viewpoint of slimming the organic light emitting display device. In consideration of this viewpoint, the inorganic layers and the organic layers may be laminated with 2 to 30 layers, respectively. That is, when one inorganic layer and one organic layer which are laminated are referred to as a pair of layers, 2 to 30 pairs of layers may be formed.

An overall thickness of the encapsulation layer may be in the range of about 10 μm to about 100 μm. The thickness of the encapsulation layer is a thickness set by considering protection of the organic light emitting diode unit and slimness of the organic light emitting display device.

The inorganic layers 531 and 551 included in the encapsulation layer 500 may be the same kind of inorganic thin layer and may be different kinds of inorganic thin layers. Similarly, the organic layers 532 and 552 included in the encapsulation layer 500 may be the same kind of organic thin layer and may be different kinds of organic thin layers. Here, the same kind or the different kinds is a concept representing a kind of thin layer distinguished by a difference in a material of the thin layer or a laminating method.

The kind of organic layer may depend on a characteristic of the used organic material and a method of polymerizing monomers for forming the organic layer. The organic layer may be formed by using a known organic thin film material in the art. The organic thin film material is not particularly limited.

For example, the organic layer may be formed by forming a film through a method such as evaporation, silkscreen, coating or the like by using liquid monomers or gel-stated monomers in which a liquid state and a solid state coexist with each other, and then photo-polymerizing the formed film by ultraviolet light or visible light. The monomers which may be applied to the above method include, for example, diazo-based, azide-based, acryl-based, polyamide-based, polyester-based, epoxide-based, polyether-based, urethane-based monomers and the like. These monomers may be used either alone or in combinations of two kinds or more.

Meanwhile, the organic layer may be formed by a thermal polymerization method in which radicals are generated by heating the monomers and then reaction starts. In this case, usable monomers include monomers such as polystyrene-based, acryl-based, urea-based, isocyanate-based, xylene-based resins and the like. These monomers may be used either alone or in combinations of two kinds or more.

The organic layer may be formed by another method which is known in the art, and for example, the organic layer may be formed by an atomic layer deposition or chemical vapor deposition (CVD) method.

A material and a laminating method of the inorganic thin layer are not particularly limited so long as being known in the art.

For example, the material for inorganic thin layer includes silicon nitride, aluminum nitride, zirconium nitride, titanium nitride, hafnium nitride, tantalum nitride, silicon oxide, aluminum oxide, titanium oxide, zirconium oxide, magnesium oxide, tin oxide, cerium oxide, silicon oxide nitride (SiON), ITO, and the like. As a deposition method thereof, a vacuum film formation method such as sputtering, chemical vapor deposition (CVD), e-beam, thermal deposition and thermal ion beam assisted deposition (IBAD) may be used. The CVD method may include induced coupled plasma-chemical vapor deposition (ICP-CVD), capacitively coupled plasma (CCP)-CVD, surface wave plasma (SWP)-CVD methods and the like.

In general, the inorganic layer may have a thickness of about 0.1 μm to about 1 μm for each layer, and the organic layer may have a thickness of about 0.5 μm to about 3 μm for each layer. Further, a refractive index of the inorganic layer may be in the range of about 1.6 to about 2.5, and a refractive index of the organic layer may be in the range of about 1.3 to about 1.5.

Meanwhile, the lens layer 510 may be made of an organic material. That is, the material applied to formation of the organic layer may be applied to formation of the lens layer 510 as it is. As such, the lens layer 510 may also be one of the organic layers.

According to one embodiment, an acryl-based polymer resin may be used as an organic material for forming the lens layer 510. The acryl-based polymer resin includes polymethylmethacrylate (PMMA).

The lens layer 510 may be formed by etching using a photoresist and may be formed by a photo-polymerization method using a lens pattern. For example, in the forming process of the encapsulation layer 500, after an organic material is coated on the inorganic layer 531 to form the organic layer, a mold 600 having a lens shape is disposed on the organic layer and the organic layer is pressed to form a plurality of lens shapes on the organic layer, and then the organic layer with the plurality of lens shapes is cured, thereby forming the lens layer 510. In this case, in the curing process, the photo-polymerization method may be applied, and the organic layer with the plurality of lens shapes is cured by irradiating light.

Referring to FIG. 3, a planarization layer made of an organic material may be formed on the lens layer 510. The planarization layer corresponds to the organic layer 552 as a layer made of an organic material. The planarization layer may be formed by using a material having a lower refractive index than the lens layer 510.

The lens layer 510 may serve to change a path of light. That is, the lens layer 510 collects light generated from the emission layer 300 in an upper direction to improve light extraction efficiency of the organic light emitting display device. While the light generated from the emission layer 300 passes through the lens layer 510, the path of light is changed to a top direction to collect the light.

In the organic light emitting display device, when the light generated from the emission layer 300 is emitted outside through the encapsulation layer 500, the light may be refracted or reflected due to a difference in a refractive index between media on an interface. Particularly, in the case where an incident angle is large, possibility that total reflection occurs is increased. During progressing of the light, when the total reflection occurs on the interface, the light progresses along the interface and the light progressing along the interface is not emitted outside but dissipated. However, when the lens layer 510 is disposed on the progressing path of the light, the path of the light is changed by the lens layer 510, thereby reducing an amount of the total-reflected light.

Meanwhile, when a distance between the lens layer 510 and the emission layer 300 is increased, an image distortion or image blurring phenomenon that images of the adjacent pixels are overlapped with each other occurs.

This will be described with reference to FIG. 4. Referring to FIG. 4, first light L1 and second light L2 which are emitted from a first emission unit A are refracted through curved surfaces of respective lenses 512 and 513 formed on respective lens layers. In this case, when an observer who observes an image displayed in the first emission unit A recognizes the first light L1 and the second light L2, a place where the first emission unit A is positioned is recognized as virtual positions A′ and A″, not a position A.

Similarly, third light L3 which is emitted from a second emission unit B near the first emission unit A is refracted through a curved surface of the lens 513 formed on the lens layer. In this case, when the observer who observes an image displayed in the second emission unit B recognizes the third light L3, a place where the second emission unit B is positioned is recognized as a virtual position B′, not a position B.

As such, when the light emitted from the first emission unit A and the light emitted from the second emission unit B are refracted, the virtual position A″ of the first emission unit A and the virtual position B′ of the second emission unit B are overlapped with each other, and as a result, an image blurring phenomenon, that the image displayed in the first emission unit A and the image displayed in the second emission unit B are blurred, occurs.

In order to prevent the image blurring phenomenon, the distance between the lens layer 510 and the emission layer 300 may be decreased.

However, it is not easy to directly form the lens layer 510 on the second electrode 400. Since the second electrode 400 needs to be maintained an electric characteristic as an electron injection electrode, the second electrode 400 needs to be not damaged but protected during processing or after processing. However, if the lens layer 510 is directly formed on the second electrode 400, the second electrode 400 may be damaged in a forming process of the lens layer 510. Further, if a proper protective layer such as the lower encapsulation layer 530 does not exist on the second electrode 400, the emission layer 300 as well as the second electrode 400 may be damaged in a forming process of the lens layer 510. As such, when the second electrode 400 or the emission layer 300 is damaged, a defect of the organic light emitting display device may be caused, and as a result, in the exemplary embodiment of the present disclosure, the lens layer 510 is not directly formed on the second electrode 400.

Further, since the encapsulation layer 500 should serve to protect the first electrode 200, the second electrode 400 and the emission layer 300 which are the organic light emitting diode unit, the encapsulation layer 500 has a thickness of a predetermined value or more. In this case, when the encapsulation layer 500 is formed and then the lens layer 510 is formed thereon, it is impossible to prevent the image blurring phenomenon from occurring.

Accordingly, in one embodiment, the lens layer 510 is formed in the middle of the encapsulation layer in the forming process of the encapsulation layer 500. Since the lens layer 510 may be formed by a method such as photo-polymerization or thermal polymerization using a mold, the lens layer 510 may be formed by a continuous process included in a series of processes of forming the encapsulation layer 500. As a result, as compared with a case where the lens layer is manufactured by a separate process, the forming process of the lens layer 510 is simplified and the forming process of the encapsulation layer 500 is not complicated. As such, when the forming process of the lens layer 510 may be performed as one of the forming process of the organic layer, the forming process of the encapsulation layer 500 including the lens layer 510 is not largely different from a general forming process of the encapsulation layer.

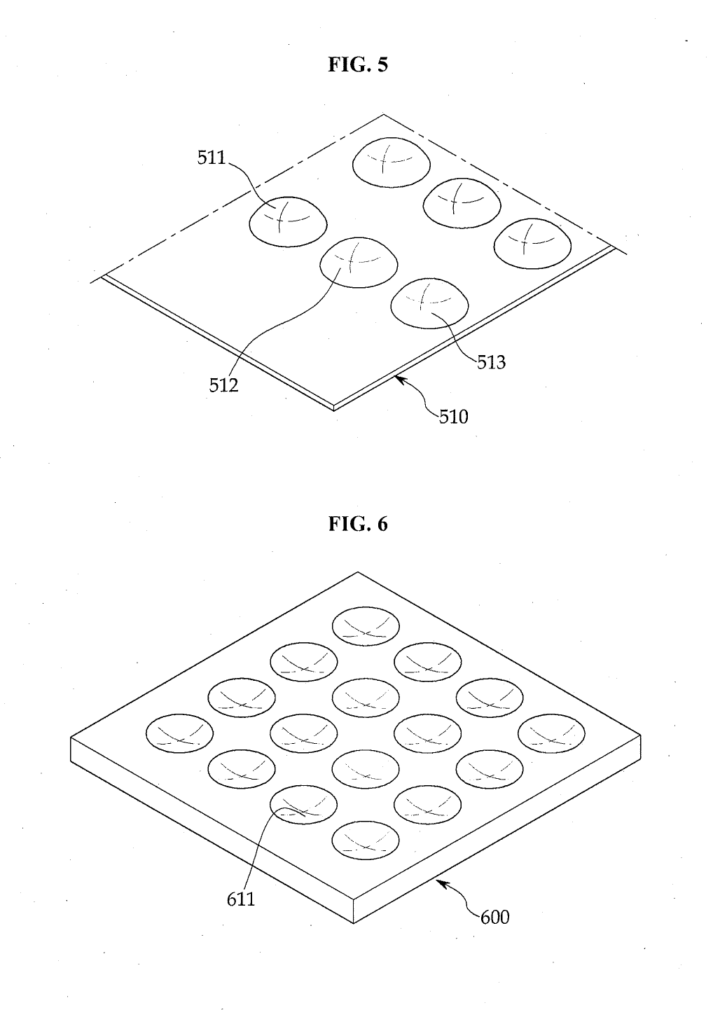

FIG. 5 is a partial perspective view illustrating a lens layer 510 in the organic light emitting display device according to one embodiment, in which shapes of a plurality of lenses 511, 512, 513 formed on the lens layer 510 are illustrated. The lens 511 has a size of a micrometer unit.

According to an embodiment, a height of the lens may be about 1 μm to about 3 μm, and a diameter of the lower portion of the lens may be 2 to 6 p.m.

FIG. 6 illustrates an example of a mold 600 for forming a lens layer. A plurality of concave portions 611 is formed on the mold. The concave portions 611 correspond to shapes of the respective lenses 511.

In the described drawings, the lens 511 is a convex lens, but the lens may be a concave lens.

Meanwhile, as illustrated in FIGS. 1 and 2, according to one embodiment, the pixel defining layer 210 is disposed at the edge of the first electrode 200 to define each pixel area by sectioning the first electrode 200 by a pixel unit, and the respective lenses 511, 512, and 513 formed on the lens layer 510 are disposed at positions corresponding to the respective pixel areas. The respective lenses 511, 512, and 513 need not to be larger than areas of the respective pixel areas. According to one embodiment, the respective lenses need to occupy about ½ or more of the areas of the respective pixel areas. When the lenses 511, 512, and 513 are larger than the pixel areas, the image blurring phenomenon occurs, and when the lenses 511, 512, and 513 are smaller than about ½ of the areas of the pixel areas, a change in the light path and an effect of the light extraction may be not large.

A method of manufacturing an organic light emitting display device according to an embodiment includes forming a first electrode on a substrate, forming an emission layer on the first electrode, forming a second electrode on the emission layer, and forming an encapsulation layer on the second electrode. Here, the forming of the encapsulation layer includes forming a lens layer having a plurality of lenses.

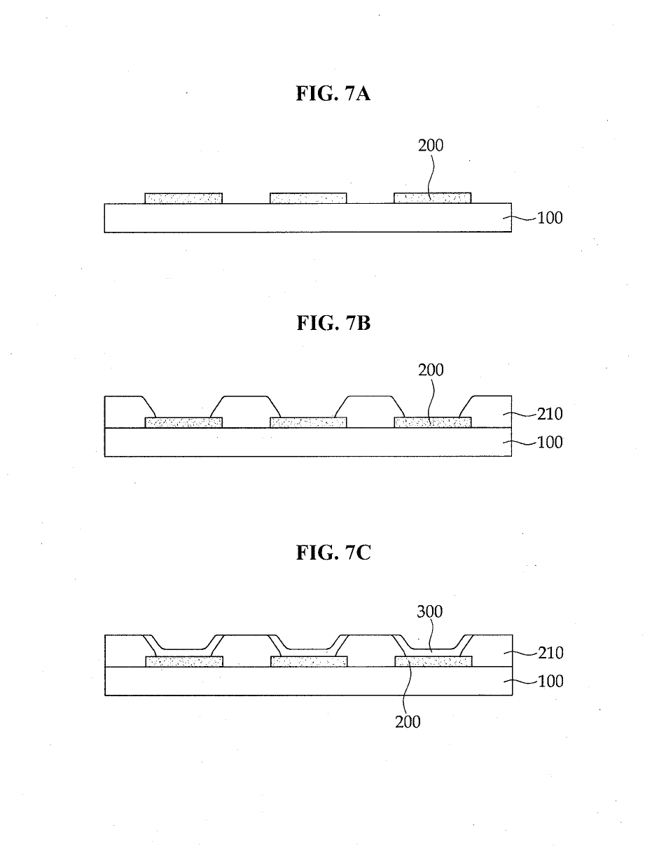

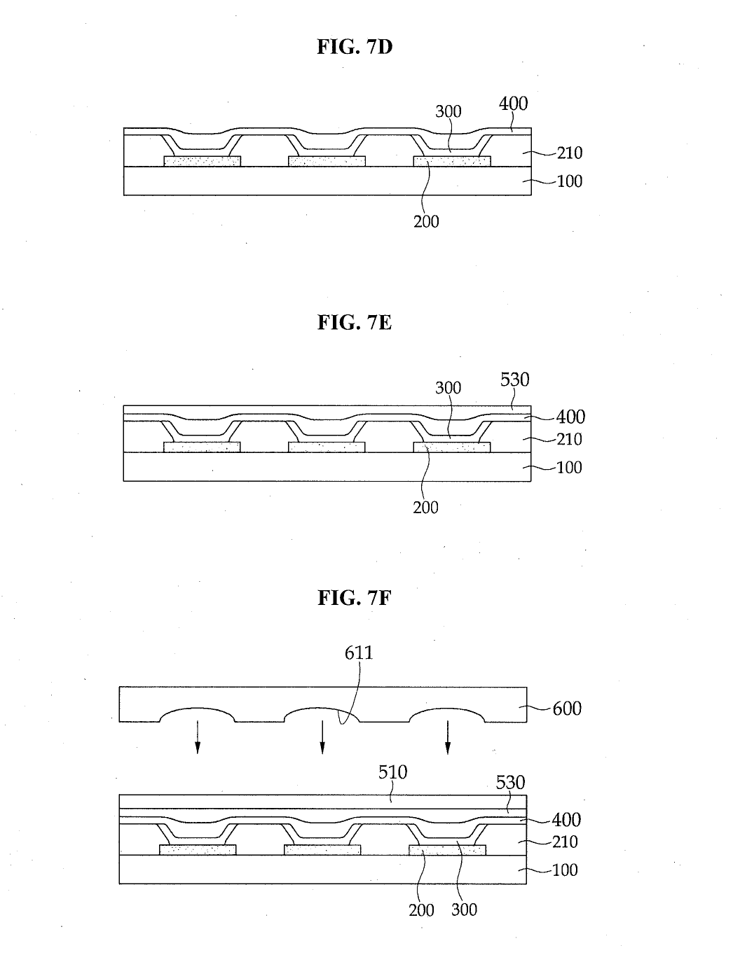

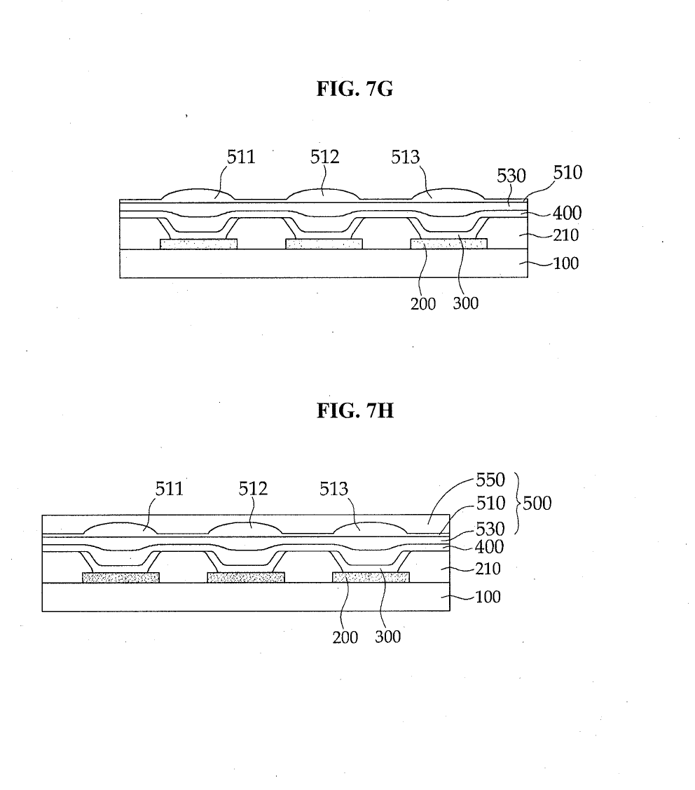

FIGS. 7A to 7H sequentially illustrate a manufacturing process of an organic light emitting display device according to another embodiment.

In order to manufacture the organic light emitting display device, first, the first electrode 200 is formed on the substrate 100 (see FIG. 7A).

The pixel defining layer 210 is formed between the first electrodes 200 (see FIG. 7B). The pixel defining layer 210 is made of an insulative material and sections the first electrodes 200 by a pixel unit. The pixel defining layer 210 is formed at an edge of the first electrode to define a formation area of the emission layer 300 and a formation area of the lens layer 510.

The emission layer 300 is formed in an opening of the first electrode 200 sectioned by the pixel defining layer by a pixel unit (see FIG. 7C). In this case, in addition to the emission layer 300, at least one of a hole injection layer, a hole transport layer, an electron transport layer and an electron injection layer may be further formed.

After forming the emission layer 300, the second electrode 400 is formed on the emission layer 300 and the pixel defining layer 210 (see FIG. 7D).

Next, the encapsulation layer 500 is formed on the second electrode 400. The forming of the encapsulation layer 500 includes forming the lower encapsulation layer 530 (see FIG. 7E), forming the lens layer 510 (see FIGS. 7F and 7G), and forming the upper encapsulation layer 550 (see FIG. 7H).

When the encapsulation layer 500 is formed on the second electrode 400, first, the lower encapsulation layer 530 is formed (see FIG. 7E). In the forming of the lower encapsulation layer 530, forming an inorganic layer made of an inorganic material and forming an organic layer made of an organic material are alternately performed. The lens layer 510 is formed on the lower encapsulation layer 530 (see FIGS. 7F and 7G).

In one embodiment, the lens layer 510 is made of an organic material. In detail, as illustrated in FIG. 7F, an organic material for forming the lens layer 510 is coated on the lower encapsulation layer 530 to form the organic layer, and a mold 600 having a lens shape is disposed on the organic layer and the organic layer is pressed to form a plurality of lens shapes on the organic layer. Thereafter, the plurality of lens shapes is cured to form the lens layer 510. In order to cure the lens shapes, light may be irradiated on the organic layer with the plurality of lens shapes.

Here, as the organic material, an acryl-based polymer may be used, and for example, polymethylmethacrylate (PMMA) may be used. Viscosity of the coated organic material for forming the lens layer 510 may be about 1,000 to about 100,000.

The lens shape is cured to form the lens layer 510 illustrated in FIG. 7G. In the forming of the lens layer 510, the respective lenses 511, 512, and 513 are formed at positions corresponding to pixel areas defined by the pixel defining layer 210. In the forming of the lens layer 510, the respective lenses need to occupy ½ or more of the areas of the respective pixel areas.

Although not illustrated in the drawing in detail, a planarization layer may be formed by using an organic material after forming the lens layer 510. Next, as illustrated in FIG. 7H, the upper encapsulation layer 550 is formed on the lens layer 510.

In the forming of the encapsulation layer 500 including the lower encapsulation layer 530, the lens layer 510 and the upper encapsulation layer 550, the forming of the inorganic layer and the forming of the organic layer may be alternately performed about 2 to about 30 times, respectively.

Although not illustrated in the drawing, forming the window member 700 may be further included after forming the encapsulation layer 500. In this case, the window member 700 may be sealed together with the substrate 100 by a sealing member and the like in an opposed state to the substrate 100. As a result, the organic light emitting display device illustrated in FIG. 2 may be obtained.

According to at least one of the disclosed embodiments, it is possible to enhance the light emission efficiency of an organic light emitting display by providing a lens layer on an encapsulation layer. Further, it is possible to enhance the light emission efficiency by increasing display luminance while minimizing or substantially preventing image distortion or image blurring by forming a lens layer on an encapsulation layer which is close to an emission layer.

From the foregoing, it will be appreciated that various embodiments of the present disclosure have been described herein for purposes of illustration, and that various modifications may be made without departing from the scope and spirit of the present disclosure. Accordingly, the disclosed embodiments are not intended to be limiting, with the true scope and spirit being indicated by the following claims.

What is claimed is:

1. An organic light emitting display device, comprising:
a substrate;
a first electrode formed over the substrate;
an emission layer formed on the first electrode;
a second electrode formed on the emission layer;
an encapsulation layer formed on the second electrode; and
a lens layer comprising a plurality of lenses formed in the encapsulation layer.

2. The organic light emitting display device of claim 1, wherein the encapsulation layer comprises an inorganic layer and an organic layer which are alternately provided.

3. The organic light emitting display device of claim 2, wherein the encapsulation layer comprises 2 to 30 pairs of alternately formed inorganic and organic layers.

4. The organic light emitting display device of claim 2, wherein the lens layer is formed of an organic material.

5. The organic light emitting display device of claim 4, wherein the organic material comprises an acryl-based polymer resin.

6. The organic light emitting display device of claim 5, wherein the acryl-based polymer resin comprises polymethylmethacrylate (PMMA).

7. The organic light emitting display device of claim 4, further comprising a planarization layer formed of an organic material disposed on the lens layer.

8. The organic light emitting display device of claim 1, further comprising a pixel defining layer disposed at an edge of the first electrode to section the first electrode by a pixel unit and define pixel areas, wherein the respective lenses formed on the lens layer are disposed at positions corresponding to the pixel areas.

9. The organic light emitting display device of claim 8, wherein the respective lenses occupy about ½ or more of the areas of the respective pixel areas.

10. A method of manufacturing an organic light emitting display device, comprising:
forming a first electrode over a substrate;
forming an emission layer on the first electrode;
forming a second electrode on the emission layer;
forming an encapsulation layer on the second electrode; and
forming a lens layer, comprising a plurality of lenses, in the encapsulation layer.

11. The method of claim 10, wherein the forming of the encapsulation layer comprises alternately forming an inorganic layer and an organic layer.

12. The method of claim 11, wherein the alternately forming is repeated 2 to 30 times.

13. The method of claim 10, wherein the forming of the encapsulation layer comprises forming a lower encapsulation layer, forming a lens layer, and forming an upper encapsulation layer.

14. The method of claim 13, wherein the forming of the lens layer comprises:
forming an organic layer on the lower encapsulation layer;
forming a plurality of lens shapes by disposing a mold with a lens shape on the organic layer and pressing the organic layer; and
curing the lens shapes.

15. The method of claim 14, wherein the curing comprises irradiating light to the lens shapes.

16. The method of claim 14, wherein the organic layer is formed of an acryl-based polymer.

17. The method of claim 16, wherein the acryl-based polymer comprises polymethylmethacrylate (PMMA).

18. The method of claim 10, further comprising:
forming a pixel defining layer at the edge of the first electrode, after forming the first electrode,
wherein in the forming of the lens layer, the respective lenses are formed at positions corresponding to the pixel areas defined by the pixel defining layer.

19. The method of claim 18, wherein in the forming of the lens layer, the lens occupies about ½ or more of an area of the pixel area.
